(19) United States
(12) Patent Application Publication
(10) Pub. No.: US 2025/0226155 A1
(43) Pub. Date: Jul. 10, 2025

(54) MULTILAYER CERAMIC CAPACITOR AND METHOD FOR MANUFACTURING THE SAME

(71) Applicant: TAIYO YUDEN CO., LTD., Tokyo (JP)

(72) Inventor: Maiko YAMANE, Tokyo (JP)

(73) Assignee: TAIYO YUDEN CO., LTD., Tokyo (JP)

(21) Appl. No.: 19/092,286

(22) Filed: Mar. 27, 2025

Related U.S. Application Data
(63) Continuation of application No. PCT/JP2023/032237, filed on Sep. 4, 2023.

(30) Foreign Application Priority Data
Oct. 7, 2022 (JP) 2022-162277

(51) Int. Cl. H01G 4/30; H01G 4/232; H05K 1/18

(52) U.S. Cl. CPC H01G 4/30; H01G 4/2325; H05K 1/181; H05K 2201/10015

(57) ABSTRACT

The multilayer ceramic capacitor pertaining to one aspect of the present invention includes: a ceramic element body having a laminate having a rectangular parallelepiped shape, a plurality of internal electrodes facing each other in the stacking direction, and a dielectric layer disposed between the plurality of internal electrodes, wherein the internal electrode ends are drawn out to a pair of end surfaces disposed parallel to the stacking direction and facing each other, a protective portion disposed on the top and bottom surfaces of the laminate in the stacking direction and a side margin portion disposed on a pair of lateral surfaces that are orthogonal to both the top and bottom surfaces and the end surfaces of the laminate, and covering the ends of the internal electrodes that are extended at the lateral surfaces, and an external electrode structure including a first base electrode disposed on the end surface of the ceramic element body and electrically connected to the ends of the internal electrode, a base ceramic layer disposed on the end surface of the ceramic element body and in contact with the circumferences of the first base electrode and a second base electrode covering the first base electrode and the base ceramic layer and electrically connected to the first base electrode.

### CROSS-REFERENCE TO RELATED APPLICATIONS

This application is a bypass continuation of International Application No. PCT/JP2023/032237, filed Sep. 4, 2023, which claims the benefit of Japanese Application No. 2022-162277, filed Oct. 7, 2022, in the Japanese Patent Office. All disclosures of the documents named above are incorporated herein by reference.

### BACKGROUND OF THE INVENTION

### 1. Field of the Invention

Aspects of the invention relate to a multilayer ceramic capacitor and a method for manufacturing the same, and more particularly, to a multilayer ceramic capacitor having an external electrode electrically connected to internal electrode ends that is drawn out and exposed on an end surface of a ceramic body, and a method for manufacturing the same.

### 2. Description of the Related Art

In recent years, the miniaturization and thinning of digital electronic devices such as mobile phones has led to the miniaturization and increased capacity of multilayer ceramic capacitors, which are mounted on electronic circuit boards. A typical multilayer ceramic capacitor formed with a ceramic body and external electrodes. FIGS. 1 and 2 are schematic diagrams showing the structure of a typical multilayer ceramic capacitor. FIG. 1 is a cross-sectional view from the width direction (W), and FIG. 2 is a cross-sectional view from the length direction (L).

As shown in the figures, a typical multilayer ceramic capacitor 1 comprises a ceramic element body 10 having a rectangular parallelepiped shape and a pair of external electrodes 20a, 20b having different polarities provided on a pair of opposing end surfaces of the ceramic element body 10, and each of the external electrodes 20a, 20b has a portion that wraps around the top and bottom surfaces and both sides of the ceramic element body 10.

The ceramic element body 10 has a laminate 11 with a roughly rectangular shape, in which a plurality of internal electrodes 13 are laminated with a dielectric layer 12 sandwiched in between, and the internal electrodes 13 are alternately drawn out and exposed on each of the opposing end surfaces parallel to the stacking direction, and a side margin portion 15 that covers the ends of the internal electrodes 13 and is located on a pair of sides that are orthogonal to both the top and bottom surfaces and the end surfaces of the laminate 11. The internal electrodes 13 that are alternately drawn out and exposed on each of the opposing end surfaces are electrically connected to external electrodes 20a and 20b, which have different polarities.

Traditionally, the plating method has been used to finish the surface of the external electrodes 20a and 20b of multilayer ceramic capacitors because it is possible to form a thin, flat electrode film on the end surface of the ceramic body. When the plating method is used to form the external electrodes 20a and 20b, various types of base electrodes have been proposed taking into account the prevention of the plating solution from penetrating into the laminate 11, which is the capacitance forming part of the ceramic element body 10, the electrical connection between the internal electrode 13 which is drawn out to the edge of the ceramic element body 10 and the plating layer, and the adhesion strength of the plating layer to the ceramic element body 10.

For example, in the external electrode described in Patent Document 1, the base electrode has a sintered electrode layer formed only on the end surface so that it does not extend to the ridge of the ceramic element body, and a resin electrode layer formed to cover the sintered electrode layer and wrap around the main surface and side surface of the ceramic element body, with the plating layer formed to cover the resin electrode layer. The resin electrode layer is said to have the effect of absorbing the stress acting on the element body due to the expansion and contraction of the ceramic capacitor.

In Patent Document 1, the sintered electrode layer is formed only on the end surface so that it does not cover the ridge, so even if the part of the resin electrode layer formed on the ridge becomes thin due to barrel polishing, the stress acting on the element body from the sintered metal layer is absorbed by the resin electrode layer, so the stress on the element body can be alleviated, and as a result, it is stated that cracks are unlikely to occur.

In addition, the external electrode described in Patent Document 2 has a first sintered metal layer and a second sintered metal layer as the base electrode, and the first sintered metal layer is directly formed only on the end surface of the ceramic element body, and the second sintered metal layer is formed to cover the first sintered metal layer and wrap around the main surface and side surface of the ceramic element body.

In Patent Document 2, because the base electrode has two layers, it is said to improve resistance to external shocks compared to when there is only one layer, and also to improve resistance to moisture and plating solution penetration. Furthermore, because the first sintered metal layer is formed only on the end surface, it is said to be able to suppress the application of compressive stress to the ceramic element body.

Furthermore, the external electrode described in Patent Document 3 has a connection part (corresponding to the base electrode) that is made up of a metal layer electrically connected to the internal electrodes, a ceramic layer arranged on top of the metal layer, and an exposed part that penetrates the ceramic layer and is in contact with the metal layer. According to Patent Document 3, the connection part improves the connectivity of the electrodes, and a multilayer ceramic capacitor with low equivalent series resistance (ESR) is obtained.

### PRIOR ART DOCUMENTS

### Patent Documents

Patent Document 1: JP 2009-218354 A

Patent Document 2: JP 2015-43424 A

Patent Document 3: US 2021-0005391 A1

Patent Document 4: JP 2012-209539 A

### SUMMARY OF THE INVENTION

### Problem(s) to be Solved by the Invention

In the multilayer ceramic capacitors described in the aforementioned Patent Documents 1 to 3, stress tends to concentrate at the edges of the sintered metal layer or metal layer that is provided as the base electrode, and cracks may occur. In addition, moisture may penetrate into the capacitance formation part from the edge of the sintered metal layer or metal layer.

This invention was made in light of the above issues with conventional technology, and it aims to provide an external electrode structure and manufacturing method for multilayer ceramic capacitors with improved reliability, which prevents moisture from entering from the edges of the sintered metal layer or metal layer and cracking due to stress concentration at the edges of the sintered metal layer or metal layer in multilayer ceramic capacitors with a base electrode made of a sintered metal layer or metal layer on the end surface of the ceramic element body.

### Means for Solving the Problems

The inventor of this invention, after considering how to solve the aforementioned issues, found that by arranging a base ceramic layer around the base electrode, which is electrically connected to the internal electrodes drawn out to the end surface of the ceramic element body, it is possible to prevent moisture from entering from the end of the base electrode, and at the same time, the stress that concentrates at the end of the base electrode is dispersed in the base ceramic layer, preventing cracks that originate at the end of the base electrode, and this led to the completion of this invention.

Specifically, one aspect of the present invention for solving the aforementioned problem is a multilayered ceramic capacitor comprising:
a ceramic element body having
   a laminate having a rectangular parallelepiped shape, a plurality of internal electrodes facing each other in the stacking direction, and a dielectric layer disposed between the plurality of internal electrodes, wherein the internal electrode ends are drawn out to a pair of end surfaces disposed parallel to the stacking direction and facing each other,
   a protective portion disposed on the top and bottom surfaces of the laminate in the stacking direction and
   a side margin portion disposed on a pair of lateral surfaces that are orthogonal to both the top and bottom surfaces and the end surfaces of the laminate, and covering the ends of the internal electrodes that are extended at the lateral surfaces, and
an external electrode structure including
   a first base electrode disposed on the end surface of the ceramic element body and electrically connected to the ends of the internal electrodes,
   a base ceramic layer disposed on the end surface of the ceramic element body and in contact with the circumferences of the first base electrode and
   a second base electrode covering the first base electrode and the base ceramic layer and electrically connected to the first base electrode.

Another aspect of the present invention for solving the aforementioned problem is a method for manufacturing a multilayer ceramic capacitor comprising: (A) laminating a predetermined number of ceramic green sheets with internal electrode patterns, and then laminating a ceramic green sheet without an internal electrode pattern on the top and/or bottom surface of the laminated sheets so as to cover the internal electrode pattern, and pressing the sheets together to make a laminated green body,

(B) obtaining a green laminated chip by cutting the obtained laminated sheet to a predetermined dimension so that the ends of the internal electrode patterns are exposed on a pair of end surfaces that are parallel to the stacking direction, and a side margin portion that covers the lateral ends of the internal electrode patterns is formed on a pair of lateral surfaces that are orthogonal to both the top and bottom surfaces in the stacking direction and the end surfaces,
(C) by performing one of the following operations (C-1) to (C-3) on the resulting green laminated chip, forming a sintered body with an external electrode structure that has a first base electrode that electrically connects the exposed ends of the internal electrode patterns on each of the two end surfaces and a base ceramic layer in contact with the circumferences of the first base electrode,
(C-1) preparing a ceramic green sheet that alternately have a plurality of nickel-containing areas corresponding to the planar shape of the first base electrode formed with a nickel-containing paste and a plurality of ceramic green sheet areas, punching out the ceramic green sheet at each end surface of the green laminated chip, and attaching the ceramic green sheet to each end surface, and then firing,
(C-2) preparing a ceramic green sheet having an opening with a shape corresponding to the planar shape of the first base electrode in planar view and penetrating in the thickness direction, punching out the ceramic green sheet at each end surface of the green laminated chip, and after the ceramic green sheet being attached to each end surface, filling nickel- containing paste, which is the raw material for the first base electrode, into the opening, and then firing,
(C-3) preparing a ceramic green sheet having an opening with a shape corresponding to the planar shape of the first base electrode in planar view and penetrating in the thickness direction, punching out the ceramic green sheet at each end surface of the green laminated chip, and after the ceramic green sheet being attached to each end surface, firing the green laminated chip, and then filling conductive paste into the opening and baking, and
   (D) forming a second base electrode to cover the first base electrode and base ceramic layer formed on the obtained sintered body.

Another aspect of the present invention for solving the aforementioned problem is a method for manufacturing a multilayer ceramic capacitor comprising: (A) laminating a predetermined number of ceramic green sheets with internal electrode patterns, and then laminating a ceramic green sheet without an internal electrode pattern on the top and/or bottom surface of the laminated sheets so as to cover the internal electrode pattern, and pressing the sheets together to make a laminated green body,

(B) obtaining a green laminated chip by cutting the obtained laminated sheet to a predetermined dimension so that the ends of the internal electrode patterns are exposed on a pair of end surfaces that are parallel to the stacking direction, and a side margin portion that covers the lateral ends of the internal electrode patterns is formed on a pair of lateral surfaces that are orthogonal to both the top and bottom surfaces in the stacking direction and the end surfaces,
(C)’ forming a sintered body with an external electrode structure comprising a third base electrode that electrically connects the ends of the multiple internal electrode patterns exposed on the end surface, a first base electrode that exists in all, a part of or multiple areas on the third base electrode and base ceramic layer that contacts the circumferences of the third base electrode and the first base electrode by performing the following operations (C-4) and (C-5) or (C-6) on the obtained green laminated chip,
(C-4) forming nickel-containing layer that will become the third base electrode after firing on the pair of end surfaces where the edges of the internal electrode patterns are exposed, so that it covers the exposed edges of the internal electrode patterns by performing one of the following operations (C-4-1) to (C-4-3),
(C-4-1) preparing a ceramic green sheet that alternately has a plurality of nickel-containing areas corresponding to the planar shape of the third base electrode formed with a nickel-containing paste and a plurality of ceramic green sheet areas, punching out the ceramic green sheets at each end surface of the green laminated chip, and attaching the ceramic green sheets to each end surface,
(C-4-2) preparing a ceramic green sheet having an opening with a shape corresponding to the planar shape of the third base electrode in planar view and penetrating in the thickness direction, punching out the ceramic green sheet at each end surface of the green laminated chip, and after the ceramic green sheet being attached to each end surface, filling nickel-containing paste into the opening to form a nickel-containing layer,
(C-4-3) forming nickel-containing layers by sputtering deposition, vapor deposition, or printing,
   (C-5) forming the first base electrode in all, a part of, or multiple areas of the nickel-containing layer and the base ceramic layer in contact with the circumferences of the first base electrode by one of the following operations (C-5-1) to (C-5-3),
(C-5-1) preparing a ceramic green sheet that alternately have a plurality of nickel-containing areas corresponding to the planar shape of the first base electrode formed with a nickel-containing paste and a plurality of ceramic green sheet areas, punching out the ceramic green sheet at each end surface of the green laminated chip, and attaching the ceramic green sheet to each end surface, and then firing,
(C-5-2) preparing a ceramic green sheet having an opening with a shape corresponding to the planar shape of the first base electrode in planar view and penetrating in the thickness direction, punching out the ceramic green sheet at each end surface of the green laminated chip, and after the ceramic green sheet being attached to each end surface, filling nickel-containing paste, which is the raw material for the first base electrode, into the opening, and then firing,
(C-5-3) preparing a ceramic green sheet having an opening with a shape corresponding to the planar shape of the first base electrode in planar view and penetrating in the thickness direction, punching out the ceramic green sheet at each end surface of the green laminated chip, and after the ceramic green sheet being attached to each end surface, firing the green laminated chip, and then filling conductive paste into the opening and baking,
(C-6) forming a nickel-containing paste layer with a shape corresponding to the formation area of the third base electrode on a ceramic green sheet that alternately has a plurality of nickel-containing paste areas with a shape corresponding to the planar shape of the first base electrode and a plurality of ceramic green sheet areas, placing the ceramic green sheet so that the nickel-containing paste layer touches the pair of end surfaces where the edges of the internal electrode patterns are exposed, punching out the ceramic green sheet at each end surface of the green laminated chip, and attaching the ceramic green sheet to each end surface, and then firing, and
   (D) forming a second base electrode to cover the first base electrode and base ceramic layer formed on the obtained sintered body.

### Effect of the Invention

According to this invention, by arranging a base ceramic layer around the base electrode electrically connected to the end of the multiple internal electrodes drawn out to the end surface of the ceramic element, it is possible to suppress the intrusion of moisture from the end of the base electrode. In addition, according to the present invention, by dispersing the stress that concentrates at the edge of the base electrode to the base ceramic layer, cracks originating at the edge of the base electrode can be prevented.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic cross-sectional view of a typical multilayer ceramic capacitor, as seen from the width direction (W).

FIG. 2 is a schematic cross-sectional view of a typical multilayer ceramic capacitor, as seen from the length direction (L).

FIG. 3 is a schematic cross-sectional view of an external electrode structure of one embodiment (1-1) of the multilayer ceramic capacitor according to one aspect of the present invention, as seen from the width direction (W).

FIG. 4 is a schematic view showing the end surface of the green laminated body before the first base electrode and base ceramic layer are formed, in the external electrode structure shown in FIG. 3.

FIG. 5 is a schematic view showing the end surface of the ceramic element body after the first base electrode and base ceramic layer are formed, in the external electrode structure shown in FIG. 3.

FIG. 6 is a schematic view showing an example of the end surface of a ceramic element after forming the first base electrode with various shapes in the external electrode structure shown in FIG. 3.

FIG. 7 is a schematic cross-sectional view of an external electrode structure of another embodiment (1-2) of the multilayer ceramic capacitor according to one aspect of the present invention, as seen from the width direction (W).

FIG. 8 is a schematic view showing an example of the end surface of a ceramic element after forming the first base electrode with various shapes in the external electrode structure shown in FIG. 7.

FIG. 9 is a schematic cross-sectional view from the width direction (W) showing an example of the external electrode structure of embodiment 1-2 in a multilayer ceramic capacitor related to the first aspect, showing the state where the multilayer ceramic capacitor is soldered to the mounting substrate.

FIG. 10 is a schematic view of the state after the second base electrode (conductive resin layer) has been applied, as seen from the end surface (length direction (L)) when obtaining the external electrode structure shown in FIG. 9.

FIG. 11 is a schematic view showing an example of a method of forming a first base electrode and a base ceramic layer in contact with the circumferences of the first base electrode on the end surface of a green laminated chip by operation (C-1) in a manufacturing method for a multilayer ceramic capacitor according to another aspect of the present invention.

FIG. 12 is a schematic view showing an example of a method of forming a first base electrode and a base ceramic layer in contact with the circumferences of the first base electrode on the end surface of a green laminated chip by operation (C-2) or (C-3) in a manufacturing method for a multilayer ceramic capacitor according to another aspect of the present invention.

FIG. 13 is a schematic view showing an example of a method of forming a third base electrode, a first base electrode and a base ceramic layer in contact with the circumferences of the third and first base electrode on the end surface of a green laminated chip by operation (C-6) in a manufacturing method for a multilayer ceramic capacitor according to another aspect of the present invention.

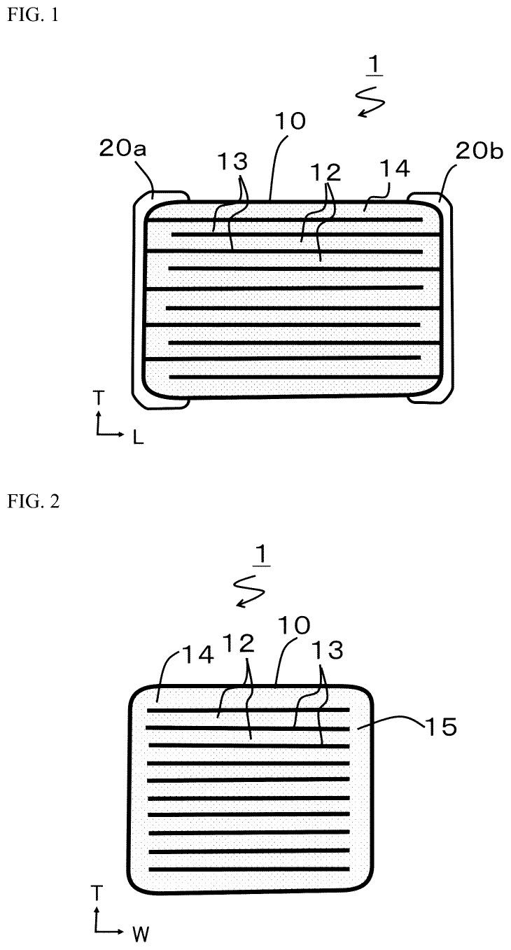

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

The following is an explanation of the embodiment for implementing the present invention with reference to the drawings, but the present invention is not limited to the embodiment and includes various other embodiments within the scope of the technical ideas described in the claims.

When using “to” to indicate a range of values, it also includes the values listed as the lower and upper limits.

### Multilayer Ceramic Capacitor

The multilayer ceramic capacitor 1 pertaining to one aspect of the present invention (hereinafter referred to as “the multilayer ceramic capacitor related to the first aspect”) has a ceramic element body 10 and an external electrode structure similar to those of conventional multilayer ceramic capacitors.

The dimensions of the multilayer ceramic capacitor are not limited, but for example, the length (L) is 0.6±0.1 mm, the width (W) is 0.3±0.08 mm, and the height (T) is 0.3±0.08 mm.

The ceramic element and external electrode structure of multilayer ceramic capacitors related to the first aspect are described below.

### <Ceramic Element>

In the multilayer ceramic capacitor 1 related to the first aspect, the ceramic element body 10 has a laminate 11 with a roughly rectangular parallelepiped shape, formed of a plurality of internal electrodes 13 facing each other in the stacking direction and a dielectric layer 12 disposed between the plurality of internal electrodes, and the ends of the internal electrodes 13 are drawn out at each of a pair of end surfaces parallel to the stacking direction, a pair of protective portions 14 located on the top and bottom surfaces of the stacking direction of the above-mentioned laminate 11, and a pair of side margin portions 15 located on a pair of sides that are orthogonal to both the top and bottom surfaces and the end surfaces of the laminate 11, and covering the ends of the internal electrodes 13 that is exposed on the sides. The internal electrodes 13 drawn out to the end surfaces described above are electrically connected to the external electrodes 20a and 20b, which have different polarities. The term “a roughly rectangular parallelepiped shape” includes shapes with rounded edges and corners, or curved edges, and refers to a shape that is roughly rectangular.

### (Dielectric Layer)

In the multilayer ceramic capacitor 1 related to the first aspect, the dielectric layer 12 is composed of dielectric ceramics obtained by firing ceramic raw material powder.

Dielectric ceramics with high dielectric constant are used to increase the capacitance of the dielectric layer. Examples of high-dielectric-constant ceramics include materials with a perovskite structure containing barium (Ba) and titanium (Ti), such as barium titanate (BaTiO₃).

The dielectric layer 12 may include strontium titanate (SrTiO₃), calcium titanate (CaTiO₃), magnesium titanate (MgTiO₃), calcium zirconate (CaZrO₃), calcium titanate zirconate (Ca(Ti, Zr)O₃), calcium barium titanate zirconate ((Ba, Ca) (Zr, Ti)O₃), barium zirconate (BaZrO₃), titanium oxide (TiO₂), etc.

In addition, the dielectric layer 12 may include glass phases other than dielectric ceramics.

In the multilayer ceramic capacitor 1 related to the first aspect, the thickness of the dielectric layer 12 after firing is preferably 1.0 μm or less, 0.5 μm or less is more preferable, and 0.3 μm or less is even more preferable. By reducing the thickness of the dielectric layer 12, the number of layers of the dielectric layer 12 can be increased, and thus the capacitance of the multilayer ceramic capacitor 1 can be increased without increasing the dimensions of the multilayer structure.

### (Internal Electrode)

In the multilayer ceramic capacitor 1 related to the first aspect, there are no particular limitation on the conductive material used to form the internal electrode 13, and at least one metal material selected from the group consisting of nickel (Ni), copper (Cu), palladium (Pd), platinum (Pt), silver (Ag), and gold (Au) can be used. In order to keep the manufacturing cost low even as the number of layers increases, it is preferable to use a metal material such as Ni or Cu as the main component, and in particular Ni is even more preferable in that it can be sintered simultaneously with the dielectric layer 12 in the present invention. When Ni is the main component of the metal material, tin (Sn) or gold (Au) may be added.

In the multilayer ceramic capacitor 1 related to the first aspect, the ends of each internal electrode 13 are drawn out every other layer on each of a pair of end surfaces parallel to the stacking direction of the above-mentioned laminate 11 and are exposed on a pair of sides orthogonal to both of the above-mentioned pair of end surfaces and the top and bottom surfaces in the stacking direction of the laminate 11.

If the positions of the ends of the multiple internal electrodes 13 exposed on the pair of sides are shifted in the stacking direction of the laminate 11, the capacitance of the resulting multilayer ceramic capacitor 1 is decreased by that amount. In addition, if the position of the end of the internal electrode 13 is shifted significantly and the end of the shifted internal electrode 13 is exposed from the side margin portion 15 located on the side of the laminate 11, it will cause a decrease in breakdown voltage and a decrease in moisture resistance.

Therefore, the misalignment between the ends of the multiple internal electrodes 13 exposed on the side of the above-mentioned laminate 11 should be within 1.0 μm in the stacking direction of the above-mentioned laminate 11.

The thickness of the internal electrode 13 is not particularly limited but is usually 0.26 μm to 1.00 μm.

### (Protective Portion and Side Margin Portion)

In the multilayer ceramic capacitor 1 related to the first aspect, the protective portion 14 and the side margin portion 15 are provided to protect the dielectric layers 12 and the internal electrodes 13 from external moisture, contamination and other forms of pollution and to prevent their deterioration over time.

There are no specific limitations on the thickness of the protective portion 14 and the side margin portion 15, but the protective portion is typically 5 μm to 75 μm thick and the side margin portion is typically 5 μm to 40 μm thick.

The materials used for the protective portion 14 and the side margin portion 15 are not particularly limited, but it is preferable that they are ceramic materials in terms of their adhesiveness to the laminate 11 and their electrical insulating properties, and it is even more preferable that they are the same as the main component of the dielectric ceramic forming the dielectric layer 12.

### <Electrode Structure (External Electrode) >

In the multilayer ceramic capacitor 1 related to the first aspect, the external electrode has a structure in which a plating layer is formed on a base electrode composed of multiple layers. And at least around the layer of the base electrode that comes into contact with the ceramic element body 11, a base ceramic layer is arranged, which forms an electrode structure together with the external electrode. In the following, the external electrode and the base ceramic layer are sometimes referred to together as the “external electrode structure”.

The following describes the external electrode structure of the multilayer ceramic capacitor 1 related to the first aspect as embodiments 1-1 and 1-2.

### Embodiment 1-1

FIG. 3 is a schematic cross-sectional view of a multilayer ceramic capacitor 1 with an external electrode structure related to the embodiment 1-1, as seen from the width direction (W).

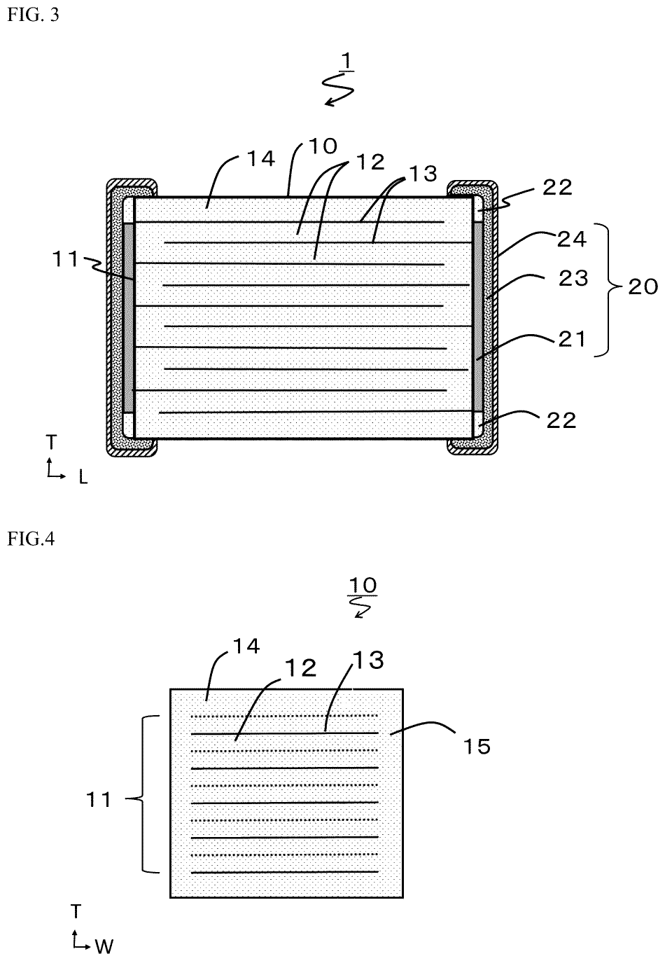

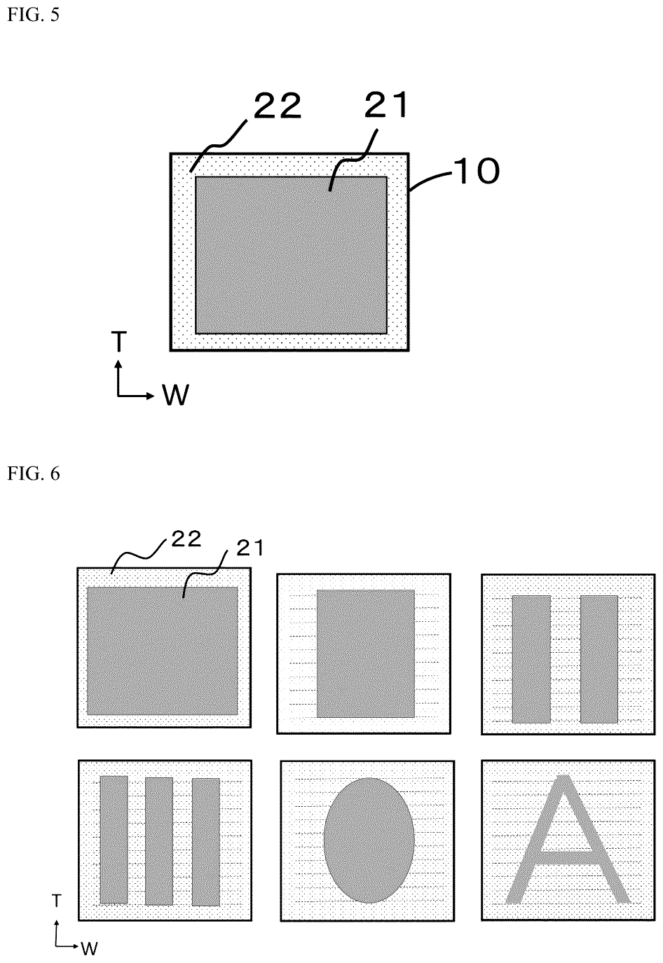

FIG. 4 is a schematic view showing the end surface of the green laminated body before the first base electrode 21 and base ceramic layer 22 are formed, and the precursors of the internal electrodes 13 drawn out to the end surface is shown as a solid line.

FIG. 5 is a schematic view showing the end surface of the ceramic element body 10 after the first base electrode 21 and base ceramic layer 22 have been formed.

As shown in FIGS. 3 to 5, the external electrode structure of the embodiment 1-1 includes a first base electrode 21 arranged on the end surface and electrically connected to internal electrodes 13 that are drawn out to a pair of end surfaces of a ceramic element body 10, a base ceramic layer 22 that contacts the circumference of the first base electrode 21, and a second base electrode 23 covering the first base electrode 21 and the base ceramic layer 22 and electrically connected to the first base electrode 21. The external electrode structure of the embodiment 1-1 has a plating layer 24 that covers the second base electrode 23.

In the outer electrode structure of embodiment 1-1, as viewed from the length direction (L), the base ceramic layer 22 is in contacts the outer circumference of the first base electrode 21, so that (i) moisture is difficult to penetrate from the edge of the first base electrode 21, (ii) the capacitive portion can be protected from external impacts, and (iii) stress concentrated at the edge of the first base electrode 21 can be dispersed. In addition, (iv) the base ceramic layer 22 is formed over the stacking direction of the internal electrode 13 (see FIG. 5), so it is possible to suppress delamination that occurs along the stacked surface. In particular, in the case of the side margin retrofitting method described below, a base ceramic layer 22 can be formed across the area from the retrofitted side margin portion 15 to the protective portion 14 at the corners of the ceramic element body 10 (see FIG. 2), so that delamination of the side margin portion 15, which is prone to delaminate from the corners, can be prevented. Since the first base electrode 21 is more likely to be stressed on the outside, the base ceramic layer 22 can relieve the stress if it exists in contact with at least part of the outermost circumference of the first base electrode 21. In addition, from the perspective of preventing moisture from entering, it is preferable for the base ceramic layer 22 to exist in contact with the entire circumference of the outside of the first base electrode 21.

### (First Base Electrode)

The first base electrode 21 only needs to satisfy the condition of being electrically connected to the internal electrodes 13 that is drawn out to the end surfaces of the ceramic element body 10, and it may exist in the entire width direction, which is perpendicular to the stacking direction of the laminate 11, of the end surfaces, a part of the width direction of the end surfaces, or multiple parts of the width direction of the end surfaces.

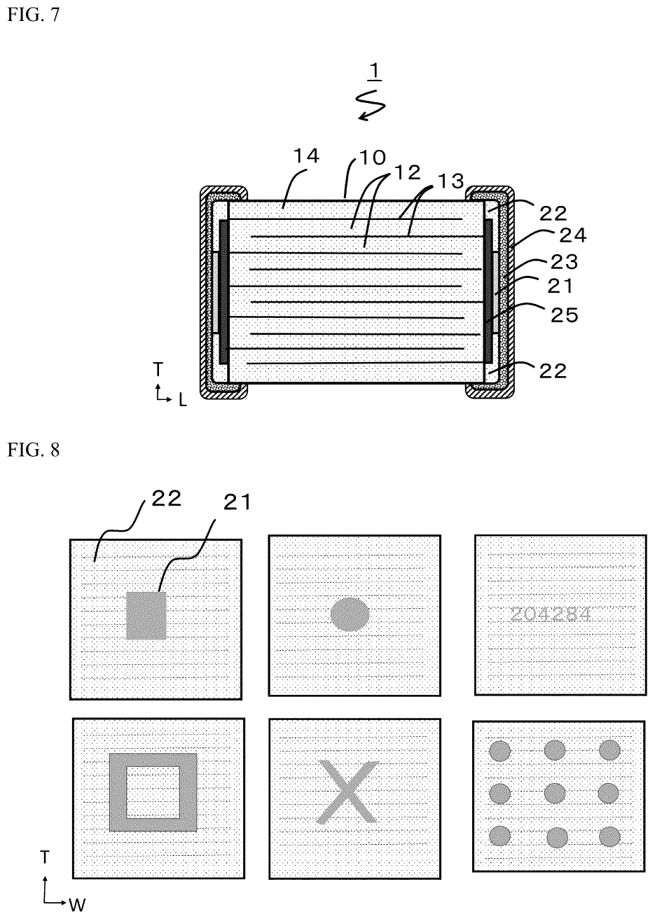

FIG. 6 is a schematic view showing an example of the end surface of a ceramic element body 10 after forming the first base electrode 21 with various shapes, and it can be made into various shapes, including figures and letters, on the condition that it is electrically connected to the internal electrodes 13 drawn out to the end surface. In any case, a base ceramic layer 22 is arranged around the first base electrode 21. It is preferable that the first base electrode 21 is electrically connected to all the internal electrodes 13 drawn out to the end surface described above.

By increasing the area of the first base electrode 21, the connection area with the internal electrodes 13 increases, and the ESR decreases.

On the other hand, if the area of the base ceramic layer 22 is increased, the capacity-forming part is protected from moisture and other external factors, so reliability improves. In addition, since the area of the first base electrode 21 is reduced, stress is reduced and cracks are less likely to form. It also increases the protection of the laminate 11, which is the part that forms the capacity, from external shocks. It is also possible to reduce the delamination of the ceramic element body 10.

The first base electrode 21 in the external electrode structure of the embodiment 1-1 can, for example, be made from a conductive material such as nickel (Ni), copper (Cu), palladium (Pd), platinum (Pt), silver (Ag), or gold (Au). From a viewpoint of cost, Ni or Cu metals are preferable. Among these, it is preferable to use a sintered metal layer, and specifically, one formed by baking a conductive paste containing various metals.

Conductive paste is made by mixing metal powder with glass components, organic binders, and organic solvents.

When using Ni for the sintered metal layer that forms the first base electrode 21, the first base electrode 21 and the base ceramic layer 22 can be formed simultaneously.

On the other hand, if a sintered metal layer with a low melting point such as Cu is used to form the first base electrode 21, it will melt at the sintering temperature of the base ceramic layer, so it is not possible to form the first base electrode 21 and the base ceramic layer 22 at the same time. For this reason, as described below, the base ceramic layer 22 is formed by firing, and then the first base electrode 21 is formed.

From the perspective of reducing the stress that the external electrode 20 exerts on the ceramic element body 10, it is preferable that the base electrode 21 is a sintered metal layer of Cu, which has a lower hardness than Ni.

In the external electrode structure related to embodiment 1-1, the thickness of the first base electrode 21 is preferably in the range of 1 μm to 40 μm, and 3 μm to 10 μm is more preferable.

### (Base Ceramic Layer)

The base ceramic layer 22 is arranged on the end surface of the ceramic element body 10, in contact with the circumferences of the first base electrode 21.

It is preferable to use the same material as the main component of the dielectric ceramics used in the dielectric layer 12 as the material for forming the base ceramic layer 22.

The thickness of the base ceramic layer 22 may differ from that of the first base electrode 21, provided that it is formed in contact with the circumferences of the first base electrode 21. In other words, the base ceramic layer 22 and the first base electrode 21 do not have to be flush, and the surface of the first base electrode 21 may be concave or convex in relation to the surface of the base ceramic layer 22.

### (Second Base Electrode)

The second base electrode 23 is formed to cover the first electrode 21 and the base ceramic layer 22, and is electrically connected to the first base electrode 21. Part of the second base electrode 23 is formed by wrapping around the top and bottom surfaces and both lateral surfaces of the aforementioned ceramic element body 10.

The second base electrode 23 is composed of a conductive resin layer or a sintered metal layer such as Cu or Ni.

Since it is possible to suppress the occurrence of cracks in the ceramic element body 10, the second base electrode 23 is preferably a conductive resin layer. The conductive resin layer is made up of conductive materials (e.g. metal powders such as silver (Ag)) dispersed in thermosetting resins such as epoxy resin.

When the second base electrode 23 is made up of a sintered metal layer, it may be the same material as the first base electrode 21.

In terms of reducing the stress on the ceramic element body 10 caused by the external electrode structure, the combination of the first base electrode 21 being a sintered metal layer of Cu and the second base electrode 23 being a conductive resin layer is the most preferable.

Preferably, the thickness of the second base electrode should be in the range of 10 μm to 150 μm.

### (Plating Layer)

The plating layer 24 is formed to cover the second base electrode 23.

The plating layer 24 is preferably a two-layer structure (not shown in the figure) of nickel (Ni) plating and tin (Sn) plating on top of it.

### Embodiment 1-2

FIG. 7 is a schematic cross-sectional view of a multilayer ceramic capacitor 1 with an external electrode structure related to the embodiment 1-2, as seen from the width direction (W).

As shown in FIG. 7, the external electrode structure of embodiment 1-2 has a third base electrode 25 between the end surface of the ceramic element body 10 and the first base electrode 21, in addition to the external electrode structure of embodiment 1-1.

The third base electrode 25 is electrically connected to the multiple internal electrodes drawn out to the end surface described above, and the first base electrode 21 is arranged on the third base electrode 25 and electrically connected to the third base electrode.

The base ceramic layer 22 is arranged on the end surface of the ceramic element body 10, in contact with the circumferences of the third base electrode 25 and the first base electrode 21.

The second base electrode 23 is formed to cover the first base electrode 21 and the base ceramic layer 22, and is electrically connected to the first base electrode 21. Part of the second base electrode 23 is formed by wrapping around the top and bottom surfaces and both lateral surfaces of the aforementioned ceramic element body 10.

The plating layer 24 is formed to cover the second base electrode 23 described above, and it is preferable to have a two-layer structure (not shown in the figure) of nickel (Ni) plating and tin (Sn) plating on top of it.

In the external electrode structure of the embodiment 1-2, the drawn-out end of the internal electrodes 13 is connected to the third base electrode 25 provided on the end surface of the ceramic element body 10, and from there it is connected to the first base electrode 21 and then to the second base electrode 23, so the third base electrode 25 can be made into a thinner layer than the first base electrode 21 in the external electrode structure of the aforementioned embodiment 1-1.

Therefore, the third base electrode 25 is preferably a metal thin film layer formed by a printing method, sputtering method, vapor deposition method, etc.

In the external electrode structure related to embodiment 1-2, the thickness of the metal film that becomes the third base electrode 25 is preferably in the range of 0.1 μm to 15 μm.

In the external electrode structure of embodiment 1-2, when Ni is used as the metal contained in the third base electrode 25 and the first base electrode 21, it can be formed at the same time as the third base electrode 25, the first base electrode 21, and the base ceramic layer 22.

In terms of reducing the stress on the ceramic element body 10, the most suitable combination for the external electrode structure in embodiment 1-2 is a combination of a Ni thin film for the third base electrode 25, a sintered Cu metal layer for the first base electrode 21, and a conductive resin for the second base electrode 23.

In terms of the connectivity of each layer, the combination of the third base electrode 25 being a thin film of Ni, the first base electrode 21 being a sintered metal layer of Ni, and the second base electrode 23 being a conductive resin is the most preferable.

In the external electrode structure of embodiment 1-2, the drawn-out end of the internal electrodes 13 is connected to the third base electrode 25 provided on the end surface of the ceramic element body 10, and from there it is connected to the first base electrode 21 and then to the second base electrode 23, so the first base electrode 21 can be any shape.

FIG. 8 is a schematic view showing examples of the end surfaces of ceramic element bodies 10 after forming the first base electrode 21 with various shapes, in order to show examples of the shape of the first base electrode 21.

As shown in FIG. 8, the first base electrode 21 can be made into various shapes, including figures and letters, as long as it is within the range where the third base electrode 25 is formed. In particular, by making the shape of the first base electrode 21 into letters or numbers, it is possible to add a lot number, etc.

In all cases, a base ceramic layer 22 is present around the first base electrode 21.

In a more preferable form of the external electrode structure pertaining to embodiment 1-2, the first base electrode 21 is provided biased in one direction of the stacking direction of the ceramic element body 10, and the second base electrode 23 is provided biased in one direction of the stacking direction to cover the first base electrode 21.

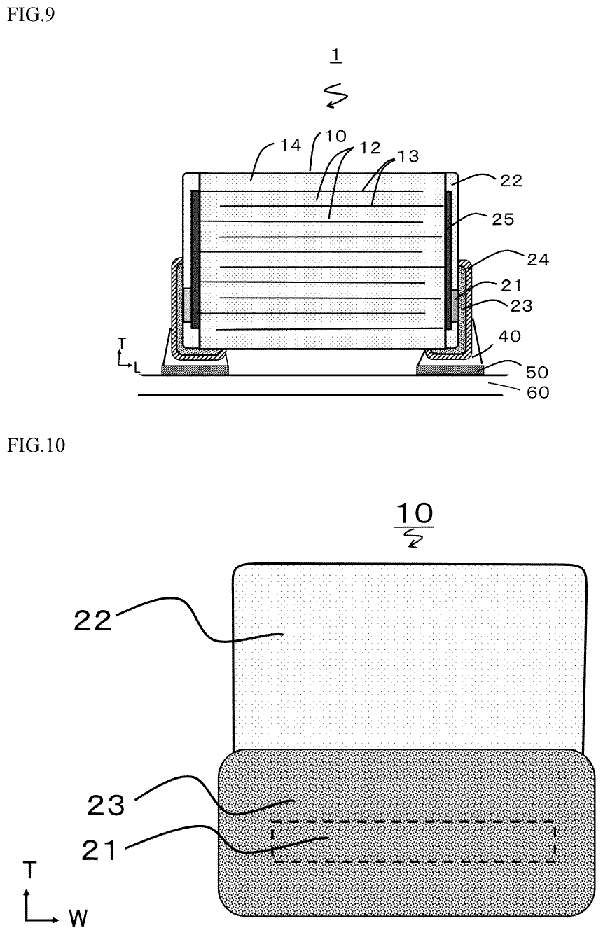

FIG. 9 is a schematic cross-sectional view from the width direction (W) of a multilayer ceramic capacitor 1 with the above-described preferred structure soldered to a mounting substrate, and shows 30 as solder, 40 as an electrode pad, and 50 as a mounting substrate, respectively.

FIG. 10 is a schematic view showing the state of the second base electrode 23 (conductive resin layer) after it has been applied to the end surface of the ceramic element body 10 to obtain the external electrode structure shown in FIG. 9. FIG. 10 shows the state in which the first base electrode 21, indicated by the dotted line, is biased downward in the stacking direction of the ceramic element body 10, and the second base electrode 23 (conductive resin layer) is biased downward in the stacking direction of the element body 10 and covers the first base electrode 21.

As shown in FIG. 9 and FIG. 10, the first base electrode 21 is biased downward in the stacking direction (height direction T) of the ceramic element body 10, and the second base electrode 23 and plating layer 24 are biased downward in the aforementioned stacking direction, covering the first base electrode 21. Part of the second base electrode 23 (conductive resin layer) and plating layer 24 are provided around the lateral surface of the ceramic element body 10.

The external electrode structure shown in FIGS. 9 and 10 means that the multilayer ceramic capacitor 1 requires only a small amount of solder when soldering to the mounting substrate 50. Also, since the solder does not turn upwards, it prevents the chip from standing up. Furthermore, when mounted on the mounting substrate 50, the conductive path through the conductive resin layer, which is the second base electrode 23, is shortened, so the ESR can be reduced.

### [Method for Manufacturing a Multilayer Ceramic Capacitor]

Another aspect of the present invention is a method for manufacturing a multilayer ceramic capacitor (hereinafter referred to as “a method for manufacturing a multilayer ceramic capacitor related to the second aspect”), which includes manufacturing a green laminated chip and forming an external electrode structure on the end surface of the obtained green laminated chip, where the internal electrode pattern is exposed, using a ceramic green sheet.

### <Manufacturing a Green Laminated Chip>

In the manufacturing method for multilayer ceramic capacitors related to the second aspect, an example of the manufacturing method for green laminated chips containing:
(A) laminating a predetermined number of ceramic green sheets with internal electrode patterns, and then laminating a ceramic green sheet without an internal electrode pattern on the top and/or bottom surface of the laminated sheets so as to cover the internal electrode pattern, and pressing the sheets together to make a laminated green body, and
(B) obtaining a green laminated chip by cutting the obtained laminated sheet to a predetermined dimension so that the ends of the internal electrode pattern are exposed on a pair of end surfaces that are parallel to the stacking direction, and a side margin portion that covers the lateral ends of the internal electrode pattern is formed on a pair of lateral surfaces that are orthogonal to both the top and bottom surfaces in the stacking direction and the end surfaces.

### Manufacturing Ceramic Green Sheets

Ceramic green sheets are manufactured by adding a binder and solvent to ceramic raw material powder, mixing them in a ball mill to produce a slurry, and then applying and drying the slurry to the surface of a base material such as plastic film using a coating machine such as a doctor blade or die coater.

The thickness of the slurry applied to the base material should be applied so that the thickness after firing is 0.6 μm or less.

### Forming Internal Electrode Patterns

There are no limitations on the method of forming the internal electrode pattern on the obtained ceramic green sheet, but it is preferable to form it using a printing method. The following describes formation using a printing method.

A conductive paste for forming internal electrodes is made by mixing conductive materials and binders. There are no limitations on the conductive material, and at least one metal material selected from the group consisting of nickel (Ni), copper (Cu), palladium (Pd), platinum (Pt), silver (Ag), gold (Au), and alloys of these metals is used, with Ni and Cu being particularly preferred. In addition, conductive paste for forming internal electrodes may contain a powder with a composition similar to that of the ceramic, which is the main component of the ceramic green sheet, in order to increase the adhesion strength of the internal electrode to the dielectric layer of the laminate after firing. In this case, the composition of the ceramic powder may differ slightly from that of the ceramic, which is the main component of the ceramic green sheet, but it is preferable to use the same composition in order to increase the adhesion strength with the dielectric layer. The binder and solvent used should be selected as appropriate so that the ceramic green sheet does not swell during printing.

Next, using the conductive paste for forming internal electrodes described above, an internal electrode pattern is formed on the surface of the ceramic green sheet described above by screen printing, gravure printing, etc.

### Laminating and Pressure Bonding (A)

After a predetermined number of ceramic green sheets with the internal electrode pattern described above have been laminated, a ceramic green sheet without the internal electrode pattern is laminated on the top and/or bottom surface of the laminated sheets so as to cover the internal electrode pattern.

If the ceramic green sheet with the internal electrode pattern on the top or bottom surface of the laminate is sufficient to protect the laminate, it is sufficient to laminate the ceramic green sheet without the internal electrode pattern on either the top or bottom surface of the laminate.

Next, the above-mentioned stacked ceramic green sheets are pressed together to form a laminated sheet. The pressing process allows the resulting laminated sheet to be made more dense.

### Cutting (B)

The obtained laminated sheet is cut into a predetermined chip size so that the ends of the internal electrode pattern are exposed on a pair of end surfaces that are parallel to the stacking direction, and side margin portions that cover the lateral surface ends of the internal electrode pattern are formed on a pair of lateral surfaces that are orthogonal to both the top and bottom surfaces of the stacking direction and the end surfaces, to obtain a green laminated chip. For cutting, push cutters or rotary cutters can be used.

Due to such factors as misalignment of the pattern during the process of forming the internal electrode pattern described above or misalignment of the overlapping of the ceramic green sheets during the process of forming the laminated sheet described above, misalignment of the overlapping of the multiple internal electrodes 13 in the laminated sheet may occur.

If the position of the lateral surface edges of the multiple internal electrodes 13 covered by the side margin portion of the above-mentioned green laminated chip shifts in the stacking direction due to a misalignment of the overlapping of the internal electrodes 13 in the laminated sheet, the capacity of the resulting laminated ceramic capacitor will decrease by that amount. In addition, if the lateral surface edge of the internal electrode 13 is significantly displaced and the displaced edge of the internal electrode 13 is exposed from the side margin portion 15 formed on the lateral surface of the ceramic element body 10, this will cause a decrease in breakdown voltage and a decrease in moisture resistance.

Therefore, it is preferable to keep the positional deviation between the edges of the multiple internal electrodes 13 in the lateral surface due to the overlap misalignment of the aforementioned internal electrode 13 within 1.0 μm in the stacking direction.

Manufacturing of Green Laminated Chips with the Side Margin Portion Added Afterwards (B)’

In order to keep the positional deviation of the lateral surface edges of the multiple internal electrodes 13 within 1.0 μm, it is necessary to print the internal electrodes 13 with high precision so that there is no overlap deviation, and to laminate the green sheets with high precision. In particular, as multilayer ceramic capacitors become smaller and have higher capacities due to an increase in the number of layers, more precise printing and laminating is required, and means to achieve this are needed.

To solve this problem, a method of attaching the unfired side margin portion afterwards (side margin retrofitting method) has been adopted.

According to this method, the thin side margin portion can reliably protect the lateral surfaces of the laminate 11, and it can also eliminate the deviation in the position of the width direction end of the multiple internal electrodes along the stacking direction, so it is advantageous for miniaturizing and increasing the capacity of the multilayer ceramic capacitor.

In the side margin retrofitting method, the above-mentioned laminated sheet is cut, and a green laminated chip is obtained in which the edges of the internal electrode pattern are exposed on a pair of end surfaces that are parallel to the stacking direction, as well as on a pair of lateral surfaces that are orthogonal to both the top and bottom surfaces of the stacking direction and the end surfaces.

Various methods have been proposed for attaching side margin portions 15 to the lateral surfaces of the green laminated chips, but the method of forming side margin portions on the lateral surfaces of the green laminated chips by punching out ceramic green sheets on the lateral surfaces of the green laminated chips (see Patent Document 4 above; hereinafter, the method of punching out ceramic green sheets on the surfaces of the green laminated chips is sometimes simply referred to as the “punching method.”) is preferred.

In the manufacturing method for multilayer ceramic capacitors related to the second aspect, the obtained laminated sheet is cut to the predetermined chip dimensions so that the edges of the internal electrode pattern are exposed on a pair of end surfaces that are parallel to the stacking direction, and also exposed on a pair of lateral surfaces that are orthogonal to both the top and bottom surfaces of the stacking direction and the pair of end surfaces, to obtain an green laminated chip, and then a side margin portion is formed on each of the lateral surfaces of the obtained green laminated chip by punching out a ceramic green sheet on each of the lateral surfaces.

### <Manufacturing External Electrode Structures>

In the manufacturing method for multilayer ceramic capacitors related to the second aspect, a base electrode and a base ceramic layer around it are formed on the end surface of a green laminated chip using a ceramic green sheet, and then a second base electrode and a plating layer are formed in that order to obtain an external electrode structure.

The following describes the formation method for the external electrode structure in the manufacturing method for multilayer ceramic capacitors related to the second aspect, as embodiments 2-1 and 2-2.

### Formation of the First Base Electrode and Base Ceramic Layer in Embodiment 2-1 (C)

In embodiment 2-1, by performing one of the following operations (C-1) to (C-3) on the obtained green laminated chip, a sintered body is obtained that has an external electrode structure with a first base electrode that electrically connects the exposed ends of the internal electrode pattern on each of the two end surfaces where the ends of the internal electrode pattern are exposed, and a base ceramic layer that contacts with the circumferences of the first base electrode.

### (Operation (C-1))

In the operation of (C-1), a ceramic green sheet is used that alternately has a plurality of nickel-containing areas corresponding to the planar shape of aforementioned first base electrode formed with a nickel-containing paste and a plurality of ceramic green sheet areas, and the ceramic green sheet is punched out at each end surface of aforementioned green laminated chip, and attaching the ceramic green sheets to each end surface, and then it is fired. If necessary, barrel polishing can be applied before firing.

According to this operation, by using nickel as the conductive material to form the first base electrode 21, the first base electrode and base ceramic layer can be formed simultaneously.

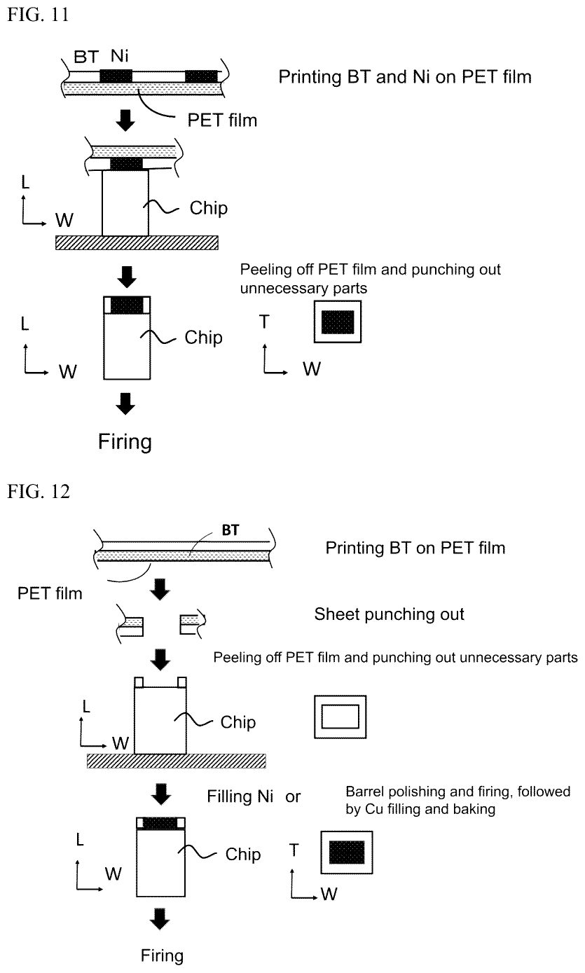

FIG. 11 shows an example of the operation of (C-1) in schematic form.

In the operation shown in FIG. 11, a nickel-containing paste prepared by adding glass components, an organic binder and an organic solvent to nickel powder is used to form the first base electrode 21, and a ceramic slurry prepared by adding a binder and an organic solvent to ceramic raw material powder is used to form the base ceramic layer 22.

After coating or printing the nickel-containing paste and ceramic slurry onto a base material sheet such as PET film to form the nickel-containing paste area and ceramic green sheet area, respectively, the base material sheet is peeled off, and the nickel-containing paste area and ceramic green sheet area are attached to the end surface of the green laminated chip where the edge of the internal electrode pattern is exposed using a punching method, and then barrel-polished and fired.

### (Operation (C-2) and (C-3))

In the operation of (C-2), a ceramic green sheet having an opening that have a shape corresponding to the planar shape of the first base electrode in planar view and penetrates in the thickness direction is used, and the ceramic green sheet is punched out at each end surface of the green laminated chip, and after the ceramic green sheet is attached to each end surface, the opening is filled with nickel-containing paste, which is the raw material for the first base electrode, and then it is fired. In this case, barrel polishing can also be applied before firing if necessary.

According to this operation, by using Ni as the conductive material to form the first base electrode, the first base electrode and the base ceramic layer can be formed at the same time.

In the operation of (C-3), a ceramic green sheet having an opening that have a shape corresponding to the planar shape of the first base electrode in planar view and penetrates in the thickness direction is used, and the ceramic green sheet is punched out at each end surface of the green laminated chip, and after the ceramic green sheet is attached to each end surface, it is fired, and then the conductive paste, which is the raw material of the first base electrode, is filled in the opening and baked. In this case, barrel polishing can also be applied before firing if necessary.

This operation is for cases where a low-melting-point metal such as Cu is used as the conductive material to form the first base electrode 21. Since the first base electrode and base ceramic layer cannot be formed at the same time, the base ceramic layer 22 and first base electrode 21 are formed in this order.

FIG. 12 shows an example of the operations in (C-2) and (C-3) in schematic form.

The operation in (C-2) is the method used when Ni is used as the first base electrode. As shown in the figure, a ceramic slurry is applied or printed onto a base material sheet to form a ceramic green sheet that forms a base ceramic layer 22, and then an opening is formed through the thickness direction, having a shape corresponding to the planar shape of the first base electrode in planar view. After that, the base material sheet is peeled off, and the ceramic green sheet is attached to the end surface of the green laminated chip, where the edges of the internal electrode pattern is exposed using a punching method. Next, the nickel-containing paste used as the raw material for the first base electrode is filled into the aforementioned opening, and then it is barrel-polished and fired.

The operation in (C-3) is a method for when the first base electrode is not formed at the same time as the firing of the green laminated chip. As shown in FIG. 12, a ceramic green sheet is formed by coating or printing a ceramic slurry that will form the base ceramic layer onto a base sheet, and then an opening is formed that has a shape corresponding to the planar shape of the first base electrode in planar view and penetrates in the thickness direction. The base sheet is then peeled off, and the ceramic green sheet is attached to the end surface of the green laminated chip where the edge of the internal electrode pattern is exposed using a punching method and fired. Next, the opening is filled with a Cu-containing paste, which is the raw material for the first base electrode, and then baked.

Formation of the third base electrode, first base electrode and base ceramic layer in embodiment 2-2 (C)’

In embodiment 2-2, the following operations (C-4) and (C-5) or (C-6) are performed on both end surfaces of the obtained green laminated chip, where the ends of the internal electrode pattern are drawn out and exposed. This results in a sintered body having an external electrode structure comprising a third base electrode 25 electrically connecting the ends of the multiple internal electrode patterns exposed on the aforementioned end surfaces, a first base electrode 21 existing in all, a part of or multiple areas on the third base electrode, and a base ceramic layer 22 contacting the circumferences of the third base electrode 25 and the first base electrode 21 arranged on a pair of end surfaces where the edges of the internal electrode pattern are exposed.

### (Operation (C-4))

In the operation (C-4), a nickel-containing layer that becomes the third base electrode is formed by firing on one of the following operations (C-4-1) to (C-4-3) to cover the end of the internal electrode patterns on the pair of end surfaces where the end of the internal electrode patterns of the aforementioned green laminated chip is exposed.

In the operation of (C-4-1), a ceramic green sheet is used that alternately has a plurality of nickel-containing areas corresponding to the planar shape of the aforementioned third base electrode formed with a nickel-containing paste and a plurality of ceramic green sheet areas, and the ceramic green sheet is punched out at each end surface of the aforementioned green laminated chip and the ceramic green sheet is attached to each end surface.

This operation is similar to the operation described in (C-1) above, and the operation described in (C-4-1) corresponds to the operation shown in the example in FIG. 11 above, where nickel-containing paste is used as the raw material for the third base electrode 25.

In the operation of (C-4-2), a ceramic green sheet having an opening that have a shape corresponding to the planar shape of the third base electrode in planar view and penetrates in the thickness direction is used, and the ceramic green sheet is punched out at each end surface of the green laminated chip, and after the ceramic green sheet is attached to each end surface, the nickel-containing paste, which is the raw material of the third base electrode, is filled in the opening to form a nickel-containing layer.

This operation is like the operation described in (C-2) above, and the operation described in (C-4-2) corresponds to the operation shown in the example in FIG. 12 above, where nickel-containing paste is used as the raw material for the third base electrode 25.

In the operation (C-4-3), a nickel-containing layer is formed by sputtering deposition, vapor deposition, or printing.

### (Operation (C-5))

In the operation of (C-5), by one of the following operations (C-5-1) to (C-5-3), the first base electrode 21 is formed on the entire area, a part of the area, or multiple areas of the nickel-containing paste layer and the base ceramic layer 22 is formed in contact with the circumferences of the first base electrode 21.

In the operation of (C-5-1), a ceramic green sheet is used that alternately has a plurality of nickel-containing paste areas with a shape corresponding to the planar shape of the first base electrode and a plurality of ceramic green sheet areas, and the ceramic green sheet is punched out at each end surface of the green laminated chip, and after the ceramic green sheet is attached to each end surface, it is fired.

This operation is like the operation described in (C-1) above, and is explained using the example shown in FIG. 11 above.

In the operation of (C-5-2), a ceramic green sheet having an opening that have a shape corresponding to the planar shape of the first base electrode in planar view and penetrates in the thickness direction is used, and the ceramic green sheet is punched out at each end surface of the green laminated chip, and after the ceramic green sheet is attached to each end surface, the opening is filled with nickel-containing paste, which is the raw material for the first base electrode, and then fired.

This operation is like the operation described in (C-2) above, and is explained in the example of filling the opening in the ceramic green sheet with Ni-containing paste in the above FIG. 12.

In the operation of (C-5-3), a ceramic green sheet having an opening that have a shape corresponding to the planar shape of the first base electrode in planar view and penetrates in the thickness direction is used, and the ceramic green sheet is punched out at each end surface of the green laminated chip, and after the ceramic green sheet is attached to each end surface, it is fired, and then the conductive paste, which is the raw material of the first base electrode, is filled in the aperture and baked.

This operation is like the operation described in (C-3) above, and is explained in the example of filling the opening with Cu-containing paste after firing the green laminated chip in the above FIG. 12.

### (Operation (C-6))

In the operation of (C-6), a nickel-containing paste layer corresponding to the shape of the area for forming the third base electrode 25 is formed on a ceramic green sheet that alternately has a plurality of ceramic green sheet areas and a plurality of nickel-containing paste areas with a shape corresponding to the planar shape of the first base electrode 21, and the ceramic green sheet is placed so that the nickel-containing paste layer for forming the third base electrode 25 contacts the pair of end surfaces where the edges of the internal electrode patterns of the green laminated chip are exposed, and the ceramic green sheet is punched out at each of these end surfaces, and the ceramic green sheet is attached to each end surface, and then fired.

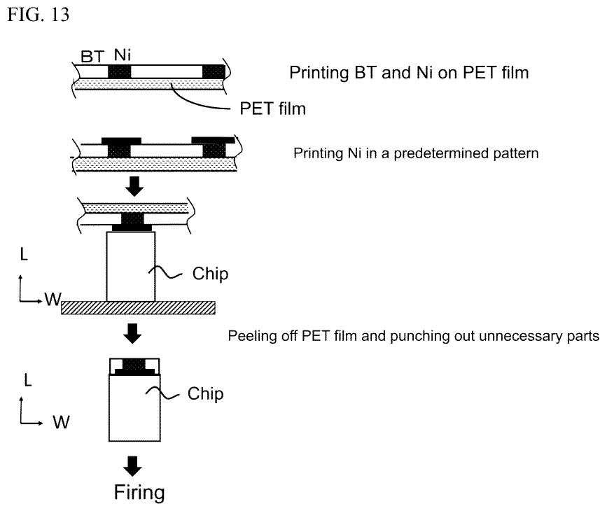

According to this operation, the first base electrode 21, the third base electrode 25, and the base ceramic layer 22 can be formed simultaneously. FIG. 13 is a schematic diagram that explains one example of the operation of (C-6).

The operation shown in FIG. 13 is like the operation shown in FIG. 11, and the nickel-containing paste for forming the third base electrode 25 and the first base electrode 21, and the ceramic slurry made by adding a binder and solvent to ceramic raw material powder for forming the base ceramic layer 22 are prepared in advance.

Next, ceramic green sheet areas and nickel-containing paste areas corresponding to the planar shape of the first base electrode 21 are alternately coated or printed onto a base material sheet such as PET film, and then a nickel-containing paste layer corresponding to the planar shape of the third base electrode 25 is formed only in the area corresponding to the formation area of the third base electrode 25. Next, the base material sheet is peeled off, and the ceramic green sheet is placed so that the nickel-containing paste layer for forming the third base electrode 25 comes into contact with the pair of end surfaces of the green laminated chip where the edges of the internal electrode patterns is exposed, and the ceramic green sheet is punched out on each end surface of the green laminated chip, and the ceramic green sheet is attached to each of these faces.

After that, the green laminated chips are fired. In this case, barrel polishing can also be carried out before firing if necessary.

### <Formation of the Second Base Electrode>

In the method for forming the external electrode structure described in the above-mentioned embodiments 2-1 and 2-2, a second base electrode 23 is formed on the obtained sintered laminated chip so as to cover the first base electrode 21 and base ceramic layer 22.

In the method for forming the external electrode structure in embodiment 2-2, if the first base electrode 21 is formed in a biased manner in one direction of the stacking direction in the ceramic element body 10 after firing, as obtained in (C-5), the second base electrode 23 is formed in a biased manner in one direction of the stacking direction so as to cover at least the circumference of the first base electrode 21 formed in a biased manner.

To form the second base electrode 23, thermosetting resin (conductive resin) such as epoxy resin, etc., in which conductive material (e.g. metal powder such as silver (Ag)) is dispersed, is preferably used.

### <Formation of the Plating Layer>

A plating layer 24 is formed to cover the second base electrode 23 described above. It is preferable to form the plating layer 24 in the order of nickel plating and tin plating.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A multilayered ceramic capacitor comprising:
a ceramic element body having
a laminate having a rectangular parallelepiped shape, a plurality of internal electrodes facing each other in the stacking direction, and a dielectric layer disposed between the plurality of internal electrodes, wherein the internal electrode ends are drawn out to a pair of end surfaces disposed parallel to the stacking direction and facing each other,
a protective portion disposed on the top and bottom surfaces of the laminate in the stacking direction and
a side margin portion disposed on a pair of lateral surfaces that are orthogonal to both the top and bottom surfaces and the end surfaces of the laminate, and covering the ends of the internal electrodes that are extended at the lateral surfaces, and
an external electrode structure including
a first base electrode disposed on the end surface of the ceramic element body and electrically connected to the ends of the internal electrodes,
a base ceramic layer disposed on the end surface of the ceramic element body and in contact with the circumferences of the first base electrode and
a second base electrode covering the first base electrode and the base ceramic layer and electrically connected to the first base electrode.

2. The multilayer ceramic capacitor according to claim 1, wherein the first base electrode exists in the entire width direction, which is perpendicular to the stacking direction of the laminate, of the end surface, in a part of the width direction of the end surface, or in multiple parts of the width direction of the end surface.

3. The multilayer ceramic capacitor according to claim 2, wherein the base ceramic layer is in contact with the outermost circumference of the first base electrode.

4. The multilayer ceramic capacitor according to claim 2, wherein the base ceramic layer is in contact with entire circumference of the first base electrode.

5. The multilayer ceramic capacitor according to claim 1, wherein the base ceramic layer is disposed over the protective portion to the side margin portion of the ceramic element body.

6. The multilayer ceramic capacitor according to claim 2, further comprising a third base electrode between the end surface of the laminate and the first base electrode, and electrically connected to the internal electrodes drawn out to the end surface, wherein
the first base electrode is arranged on the third base electrode and electrically connected to the third base electrode, and
the base ceramic layer is arranged on the end surface of the ceramic element body, in contact with the circumference of the third base electrode and the first base electrode.

7. The multilayer ceramic capacitor according to claim 6, wherein the first base electrode is biased in one direction of the stacking direction of the ceramic element body, and the second base electrode is biased in one direction of the stacking direction to cover the first base electrode.

8. The multilayer ceramic capacitor according to claim 1, wherein the positional deviation of the ends of the plurality of internal electrodes exposed on the lateral surfaces of the laminate is within 1.0 μm in the stacking direction.

9. The multilayer ceramic capacitor according to claim 1, wherein the first base electrode is a metal layer containing nickel or copper as the main component.

10. The multilayer ceramic capacitor according to claim 1, wherein the second base electrode is a conductive resin layer.

11. The multilayer ceramic capacitor according to claim 1, wherein the second base electrode is a metal layer containing nickel or copper as a main component.

12. The multilayer ceramic capacitor according to claim 6, wherein the third base electrode is a metal layer containing nickel as a main component.

13. The multilayer ceramic capacitor according to claim 1, further comprising a plating layer covering the second base electrode.

14. The multilayer ceramic capacitor according to claim 13, wherein the plating layer comprises a nickel plating layer and a tin plating layer formed on the nickel plating layer.

15. A circuit board in which the multilayer ceramic capacitor according to claim 13 is fixed to an electrode pad by solder.

16. A method for manufacturing a multilayer ceramic capacitor comprising:
(A) laminating a predetermined number of ceramic green sheets with internal electrode patterns, and then laminating a ceramic green sheet without an internal electrode pattern on the top and/or bottom surface of the laminated sheets so as to cover the internal electrode pattern, and pressing the sheets together to make a laminated green body,
(B) obtaining a green laminated chip by cutting the obtained laminated sheet to a predetermined dimension so that the ends of the internal electrode patterns are exposed on a pair of end surfaces that are parallel to the stacking direction, and a side margin portion that covers the lateral ends of the internal electrode patterns is formed on a pair of lateral surfaces that are orthogonal to both the top and bottom surfaces in the stacking direction and the end surfaces,
(C) by performing one of the following operations (C-1) to (C-3) on the resulting green laminated chip, forming a sintered body with an external electrode structure that has a first base electrode that electrically connects the exposed ends of the internal electrode patterns on each of the two end surfaces and a base ceramic layer in contact with the circumferences of the first base electrode,
(C-1) preparing a ceramic green sheet that alternately have a plurality of nickel-containing areas corresponding to the planar shape of the first base electrode formed with a nickel-containing paste and a plurality of ceramic green sheet areas, punching out the ceramic green sheet at each end surface of the green laminated chip, and attaching the ceramic green sheet to each end surface, and then firing,
(C-2) preparing a ceramic green sheet having an opening with a shape corresponding to the planar shape of the first base electrode in planar view and penetrating in the thickness direction, punching out the ceramic green sheet at each end surface of the green laminated chip, and after the ceramic green sheet being attached to each end surface, filling nickel-containing paste, which is the raw material for the first base electrode, into the opening, and then firing,
(C-3) preparing a ceramic green sheet having an opening with a shape corresponding to the planar shape of the first base electrode in planar view and penetrating in the thickness direction, punching out the ceramic green sheet at each end surface of the green laminated chip, and after the ceramic green sheet being attached to each end surface, firing the green laminated chip, and then filling conductive paste into the opening and baking, and
(D) forming a second base electrode to cover the first base electrode and base ceramic layer formed on the obtained sintered body.

17. A method for manufacturing a multilayer ceramic capacitor comprising:
(A) laminating a predetermined number of ceramic green sheets with internal electrode patterns, and then laminating a ceramic green sheet without an internal electrode pattern on the top and/or bottom surface of the laminated sheets so as to cover the internal electrode pattern, and pressing the sheets together to make a laminated green body,
(B) obtaining a green laminated chip by cutting the obtained laminated sheet to a predetermined dimension so that the ends of the internal electrode patterns are exposed on a pair of end surfaces that are parallel to the stacking direction, and a side margin portion that covers the lateral ends of the internal electrode patterns is formed on a pair of lateral surfaces that are orthogonal to both the top and bottom surfaces in the stacking direction and the end surfaces,
(C)’ forming a sintered body with an external electrode structure comprising a third base electrode that electrically connects the ends of the multiple internal electrode patterns exposed on the end surface, a first base electrode that exists in all, a part of or multiple areas on the third base electrode and base ceramic layer that contacts the circumferences of the third base electrode and the first base electrode by performing the following operations (C-4) and (C-5) or (C-6) on the obtained green laminated chip,
(C-4) forming nickel-containing layer that will become the third base electrode after firing on the pair of end surfaces where the edges of the internal electrode patterns are exposed, so that it covers the exposed edges of the internal electrode patterns by performing one of the following operations (C-4-1) to (C-4-3),
(C-4-1) preparing a ceramic green sheet that alternately has a plurality of nickel-containing areas corresponding to the planar shape of the third base electrode formed with a nickel-containing paste and a plurality of ceramic green sheet areas, punching out the ceramic green sheets at each end surface of the green laminated chip, and attaching the ceramic green sheets to each end surface,
(C-4-2) preparing a ceramic green sheet having an opening with a shape corresponding to the planar shape of the third base electrode in planar view and penetrating in the thickness direction, punching out the ceramic green sheet at each end surface of the green laminated chip, and after the ceramic green sheet being attached to each end surface, filling nickel-containing paste into the opening to form a nickel-containing layer,
(C-4-3) forming nickel-containing layers by sputtering deposition, vapor deposition, or printing,
(C-5) forming the first base electrode in all, a part of, or multiple areas of the nickel-containing layer and the base ceramic layer in contact with the circumferences of the first base electrode by one of the following operations (C-5-1) to (C-5-3),
(C-5-1) preparing a ceramic green sheet that alternately has a plurality of nickel-containing areas corresponding to the planar shape of the first base electrode formed with a nickel-containing paste and a plurality of ceramic green sheet areas, punching out the ceramic green sheet at each end surface of the green laminated chip, and attaching the ceramic green sheet to each end surface, and then firing,
(C-5-2) preparing a ceramic green sheet having an opening with a shape corresponding to the planar shape of the first base electrode in planar view and penetrating in the thickness direction, punching out the ceramic green sheet at each end surface of the green laminated chip, and after the ceramic green sheet being attached to each end surface, filling nickel-containing paste, which is the raw material for the first base electrode, into the opening, and then firing,
(C-5-3) preparing a ceramic green sheet having an opening with a shape corresponding to the planar shape of the first base electrode in planar view and penetrating in the thickness direction, punching out the ceramic green sheet at each end surface of the green laminated chip, and after the ceramic green sheet being attached to each end surface, firing the green laminated chip, and then filling conductive paste into the opening and baking,
(C-6) forming a nickel-containing paste layer with a shape corresponding to the formation area of the third base electrode on a ceramic green sheet that alternately has a plurality of nickel-containing paste areas with a shape corresponding to the planar shape of the first base electrode and a plurality of ceramic green sheet areas, placing the ceramic green sheet so that the nickel-containing paste layer touches the pair of end surfaces where the edges of the internal electrode patterns are exposed, punching out the ceramic green sheet at each end surface of the green laminated chip, and attaching the ceramic green sheet to each end surface, and then firing, and
(D) forming a second base electrode to cover the first base electrode and base ceramic layer formed on the obtained sintered body.

18. The method for manufacturing a multilayer ceramic capacitor according to claim 17, wherein the operation (C-5) is an operation of forming the first base electrode biased toward the side that will be the mounting surface of the multilayer ceramic capacitor, and operation (D) is a operation of forming the second base electrode biased toward the side that will be the mounting surface of the multilayer ceramic capacitor so as to cover at least the first base electrode formed in the biased manner and the area formed around the first base electrode in the base ceramic layer.

19. The method for manufacturing a multilayer ceramic capacitor according to claim 16, in which the following (B)’ is performed instead of (B):
(B)’ The obtained laminated sheet is cut to the predetermined chip dimensions so that the edges of the internal electrode patterns are exposed on a pair of end surfaces that are parallel to the stacking direction, and also exposed on a pair of lateral surfaces that are perpendicular to both the top and bottom surfaces in the stacking direction and the pair of end surfaces, to obtain a green laminated chip, and then a side margin portion is formed on each of the lateral surfaces of the obtained green laminated chip by punching out a ceramic green sheet on each of the lateral surfaces.

20. The method for manufacturing a multilayer ceramic capacitor according to claim 17, in which the following (B)’ is performed instead of (B):
(B)’ The obtained laminated sheet is cut to the predetermined chip dimensions so that the edges of the internal electrode patterns are exposed on a pair of end surfaces that are parallel to the stacking direction, and also exposed on a pair of lateral surfaces that are perpendicular to both the top and bottom surfaces in the stacking direction and the pair of end surfaces, to obtain a green laminated chip, and then a side margin portion is formed on each of the lateral surfaces of the obtained green laminated chip by punching out a ceramic green sheet on each of the lateral surfaces.
